(19) United States
(12) Patent Application Publication
(10) Pub. No.: US 2020/0111998 A1
(43) Pub. Date: Apr. 9, 2020

(54) METHOD FOR FORMING STACKED STRUCTURE BONDED BETWEEN INNER LAYERS BY ELECTROSTATIC FORCE AND METHOD FOR MANUFACTURING DISPLAY DEVICE

(71) Applicant: Samsung Display Co., Ltd., Yongin-Si (KR)

(72) Inventors: Seungcheol KO, Cheonan-si (KR); Junho SIM, Hwaseong-si (KR)

(21) Appl. No.: 16/585,420

(22) Filed: Sep. 27, 2019

(30) Foreign Application Priority Data
Oct. 5, 2018 (KR) 10-2018-0119191

(51) Int. Cl. H01L 51/56; H01L 51/00

(52) U.S. Cl. CPC H01L 51/56; H01L 51/0097

(57) ABSTRACT

A method for forming a stacked structure bonded between inner layers by electrostatic force is provided. According to the method, a first barrier flake charged with a first electric charge is adhered to a surface of a substrate. The first barrier flake is provided in plural. A second barrier flake is provided in a gap between adjacent first barrier flakes to form a first barrier layer charged with the first electric charge. The second barrier flake has a size smaller than a size of the first barrier flake. A second barrier layer is formed on the first barrier layer. The second barrier layer is charged with a second electric charge having a polarity opposite to the first electric charge to be combined with the first barrier layer by an electro-static force.

### CROSS-REFERENCE TO RELATED APPLICATION

This application claims priority to Korean Patent Application No. 10-2018-0119191 filed on Oct. 5, 2018, and all the benefits accruing therefrom under 35 U.S.C. § 119, the content of which in its entirety is herein incorporated by reference.

### BACKGROUND

### 1. Field

Exemplary embodiments are directed to a method for manufacturing a display device. More particularly, exemplary embodiments are directed to a method for forming a stacked structure bonded between inner layers by electrostatic force and a method for manufacturing a display device.

### 2. Description of the Related Art

In recent, research and development are being conducted for a flexible display device in order to improve portability and variability of a display device and to implement various designs.

In order to obtain the flexible display device, a polymer substrate having flexibility may be used. For example, after a carrier substrate is combined with the polymer substrate, a display element part may be formed on the polymer substrate. Thereafter, the carrier substrate may be separated from the polymer substrate to form the flexible display device.

One of known methods for separating the carrier substrate and the polymer substrate may use laser. However, when the laser is used for separating the carrier substrate from the polymer substrate, the display element part may be damaged, and uniformity of separation may be deteriorated.

### SUMMARY

In order to the above problem, a method is being developed to form a barrier adhesion layer, which is mechanically separable, by coating a graphene oxide flake between the carrier substrate and the polymer substrate.

Exemplary embodiments are directed to a method for forming a stacked structure having less defects and bonded between inner layers by electrostatic force.

Exemplary embodiments are directed to a method for manufacturing a display device with improved reliability and efficiency.

According to an exemplary embodiment, a method for forming a stacked structure bonded between inner layers by electrostatic force is provided. According to the method, a first barrier flake charged with a first electric charge is adhered to a surface of a substrate. The first barrier flake is provided in plural. A second barrier flake is provided in a gap between adjacent first barrier flakes to form a first barrier layer charged with the first electric charge. The second barrier flake has a size smaller than a size of the first barrier flake. A second barrier layer is formed on the first barrier layer. The second barrier layer is charged with a second electric charge having a polarity opposite to the first electric charge to be combined with the first barrier layer by an electro-static force.

In an exemplary embodiment, the first and second barrier flakes may include at least one of graphene, graphene oxide or hexagonal boron nitride.

In an exemplary embodiment, the surface of the substrate may be charged with the second electric charge before adhering the first barrier flake to the surface of the substrate.

In an exemplary embodiment, the substrate combined with the first barrier flakes may be dipped in a solution including the second barrier flake to provide the second barrier flake.

In an exemplary embodiment, a heating and pressure-reducing process may be performed to remove gas in the gap between the adjacent first barrier flakes with the substrate dipped in the solution to provide the second barrier flake.

In an exemplary embodiment, the heating and pressure-reducing process may be performed at about 40 degrees Celsius (° C.) to about 80° C. and at about 50 millibars (mbar) to about 300 mbar.

In an exemplary embodiment, the first barrier flake may have a size equal to or more than about 10 micrometers (μm) and equal to or less than about 50 μm.

In an exemplary embodiment, the second graphene oxide flake may have a size equal to or more than about 1 and less than about 10 μm.

In an exemplary embodiment, a thickness of the stacked structure may be about 2 nanometers (nm) to about 20 nm.

According to an exemplary embodiment, a method for manufacturing a display device is provided. According to the method, a first barrier flake charged with a first electric charge is adhered to a surface of a carrier substrate. The first barrier flake is provided in plural. A second barrier flake is provided in a gap between adjacent first barrier flakes to form a first barrier layer charged with the first electric charge. The second barrier flake has a size smaller than a size of the first barrier flake. A second barrier layer is formed on the first barrier layer. The second barrier layer is charged with a second electric charge having a polarity opposite to the first electric charge to be combined with the first barrier layer by an electro-static force. A flexible substrate is formed on a barrier adhesion layer including the first barrier layer and the second barrier layer. A protective film is formed on the display element part. The flexible substrate is separated from the carrier substrate

According to exemplary embodiments, a barrier adhesion layer is disposed between a carrier substrate and a flexible substrate. Thus, a chemical bond between the carrier substrate and the flexible substrate may be effectively prevented, and the carrier substrate may be mechanically separated from the flexible substrate without a laser-radiation process or the like.

Furthermore, when a single layer of the barrier adhesion layer is formed, after a first barrier flake is provided to form a preliminary layer, a second barrier flake smaller than the first barrier flake is provided to fill a gap where the first barrier flake is not attached. Thus, defects of the barrier adhesion layer may be reduced, thereby increasing uniformity of the barrier adhesion layer. Thus, reliability of a flexible substrate formed on the barrier adhesion layer may be improved, and separation of the flexible substrate and the carrier substrate may be easily performed.

Furthermore, since the first barrier flake and the second barrier flake are provided through combination of dipping and spraying, a manufacturing time may be reduced, and defects due to spraying may be prevented or reduced.

### BRIEF DESCRIPTION OF THE DRAWINGS

Aspects of one or more exemplary embodiments of the invention will be more clearly understood from the following detailed description taken in conjunction with the accompanying drawings.

FIGS. 1 to 6 are schematic views illustrating exemplary embodiments of a method for forming a stacked structure bonded between inner layers by electrostatic force according to the invention.

FIGS. 7 to 12 and 14 to 17 are cross-sectional views illustrating exemplary embodiments of a method for manufacturing a display device according to the invention.

FIG. 13 is a plan view illustrating an exemplary embodiment of a cutting process in a method for manufacturing a display device according to the invention.

### DETAILED DESCRIPTION

A method for forming a stacked structure bonded between inner layers by electrostatic force and a method for manufacturing a display device according to exemplary embodiments of the invention will be described hereinafter with reference to the accompanying drawings, in which some exemplary embodiments are shown. Same or similar reference numerals may be used for same or similar elements in the drawings.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

FIGS. 1 to 6 are schematic views illustrating exemplary embodiments of a method for forming a stacked structure bonded between inner layers by electrostatic force according to the invention.

Referring to FIG. 1, a surface of a substrate 100 is electric-charged. The surface of the substrate 100 may be positively electric-charged or negatively electric-charged. In the case that the surface of the substrate 100 is electric-charged, an electric-charged barrier flake with the opposite polarity may be easily combined with the surface of the substrate 100 by electrostatic force.

The barrier flake may include a material which has a two-dimensional crystalline structure, has a superior barrier ability, and can be easily electric-charged. In an exemplary embodiment, for example, the barrier flake may include graphene, graphene oxide, hexagonal boron nitride or the like. In an exemplary embodiment, the barrier flake may include a graphene oxide flake.

In an exemplary embodiment, the surface of the substrate 100 may be negatively electric-charged, and positively electric-charged graphene oxide flake may be adhered to the surface of the substrate 100. However, the invention is not limited thereto. In another exemplary embodiment, the surface of the substrate 100 may be positively electric-charged, and negatively electric-charged graphene oxide flake may be adhered to the surface of the substrate 100.

For example, in order to charge the surface of the substrate 100 with a negative electric charge, the surface of the substrate 100 may be treated with an anionic polymer electrolyte such as poly(4-styrenesulfonate) (“PSS”) or poly(acrylic)acid (“FAA”), or treated with sulfuric acid/hydrogen peroxide, oxygen plasma or the like.

For example, in order to charge the surface of the substrate 100 with a positive electric charge, the surface of the substrate 100 may be treated with a cationic polymer electrolyte such as poly(allylamine)hydrochloride (“PAH”), polydiallyldimethylammonium (“PDDA”) or poly(ethyleneimine) (“PEI”), or treated with plasma of an inert gas such as argon.

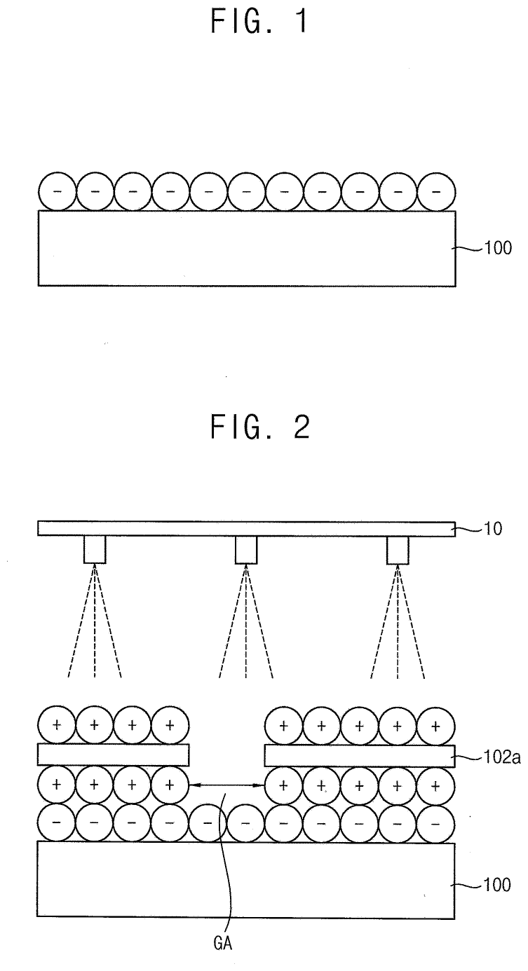

Referring to FIG. 2, a first graphene-oxide flake 102a which is positively electric-charged is adhered to the surface of the substrate 100 which is negatively electric-charged. For example, a solution including the first graphene-oxide flake 102a may be provided on the surface of the substrate 100.

In an exemplary embodiment, for example, a solvent of a graphene-oxide-flake solution may include heptane, hexane, ethanol, methanol, butanol, propanol, methylene chloride, trichloroethylene, ethyl acetate, acetone, methylethylketone, diethylamine, di-isopropylamine, isopropylamine, water or combination thereof.

In an exemplary embodiment, the graphene-oxide-flake solution may be an aqueous solution, and may be coated through a dip coating method, a spray coating method, a spin coating method, a screen coating method, an offset printing method, an inkjet printing method, a knife coating method, a gravure coating method or the like. In an exemplary embodiment, the graphene-oxide-flake solution may be provided by a spray 10.

The positively or negatively electric-charged graphene-oxide flake may be obtained through conventionally known methods. For example, since a graphene-oxide flake contains a carboxylic group, a hydroxyl group or the like, the graphene oxide may have a negative electric charge in itself. Alternatively, an oxidation agent or a reduction agent may be provided to a graphene-oxide flake to obtain the positively or negatively electric-charged graphene-oxide flake. For example, in order to obtain the positively electric-charged graphene-oxide flake, a metal salt such as magnesium salt, nickel salt or the like may be provided to a graphene-oxide flake, or a graphene oxide flake may be modified with a polymer such as polyethylene glycol.

The first graphene-oxide flake 102a may be combined with the surface of the substrate 100 by Coulomb's force (electrostatic force). If the surface of the substrate 100 is entirely covered with the graphene oxide flakes, a thickness of the graphene oxide flake, which is a thin film, is barely increased because of electrostatic repulsive forces between graphene-oxide flakes. Thus, a graphene-oxide layer having a very small thickness may be formed.

Since the graphene-oxide layer consists of graphene oxide flakes, the graphene oxide layer is not uniform and continuous, and may have defects such as a gap GA. If the graphene-oxide layer having such defects is used for a barrier adhesion layer in the process of manufacturing a display device, a structure formed on the graphene-oxide layer may be damaged by outgassing in following processes, and separation failure or wrinkles of a flexible substrate may be caused.

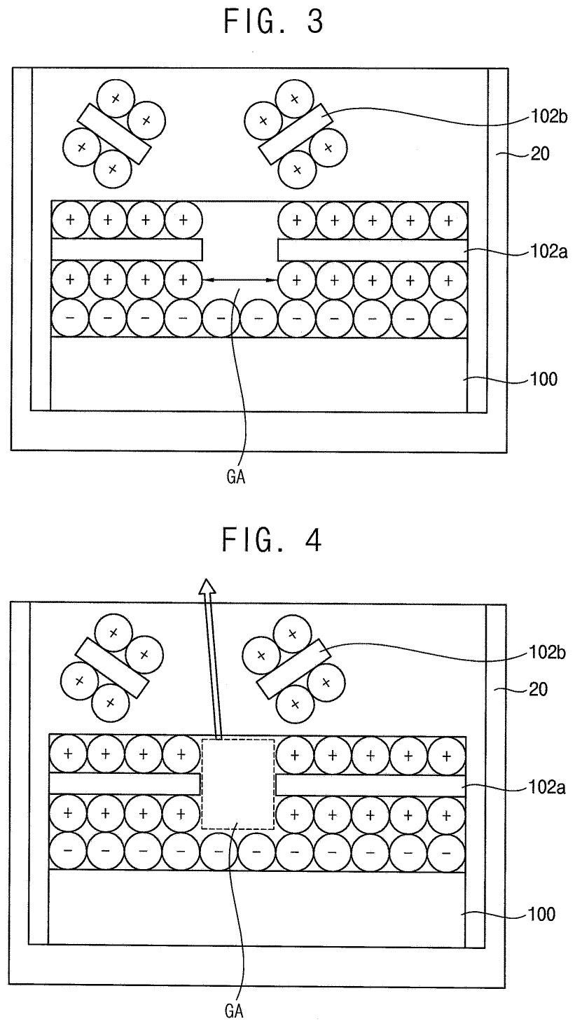

Referring to FIGS. 3 to 5, a second graphene-oxide flake 102b is provided in the gap GA of the graphene-oxide layer. Thus, the defects of the graphene-oxide layer may be removed or reduced, thereby improving uniformity of the graphene oxide layer.

For example, as illustrated in FIG. 3, the substrate 100 combined with the first graphene-oxide flake 102a may be dipped in a solution including the second graphene-oxide flake 102b.

In an exemplary embodiment, the second graphene-oxide flake 102b may have a size smaller than the first graphene-oxide flake 102a to easily enter into or fill the gap GA of the graphene-oxide layer. In an exemplary embodiment, for example, the first graphene-oxide flake 102a may have a size equal to or more than about 10 μm and equal to or less than about 50 μm, and the second graphene-oxide flake 102b may have a size equal to or more than about 1 μm and less than about 10 μm. The graphene-oxide flakes may have a two-dimensional shape such as a plate shape, and the size of the graphene-oxide flakes may be defined as a maximum diameter thereof.

In an exemplary embodiment, a concentration of the second graphene-oxide flake 102b in the solution including the second graphene-oxide flake 102b may be greater than a concentration of the first graphene-oxide flake 102a in the solution including the first graphene-oxide flake 102a. In an exemplary embodiment, for example, a concentration of the first graphene-oxide flake 102a in the solution provided by the spray 10 may be about 0.01 gram per liter (g/l) to about 0.1 g/l, and a concentration of the second graphene-oxide flake 102b in the solution provided through the dipping method may be about 0.1 g/l to about 0.5 g/l. Thus, a time for filling the gap GA may be reduced by this difference in the concentrations.

Referring to FIG. 4, a heating and pressure-reducing process may be performed to reduce gas in the gap GA of the graphene-oxide layer.

In an exemplary embodiment, the heating and pressure-reducing process may be performed to the substrate 100 combined with the first graphene-oxide flake 102a which is dipped in the solution including the second graphene-oxide flake 102b. For example, the heating and pressure-reducing process may be performed in a pressure-reducing chamber 20 in which the substrate 100 is disposed.

In an exemplary embodiment, for example, the heating temperature may be about 40° C. to about 80° C., and preferably about 40° C. to about 60° C. A pressure of the chamber 20 may be about 50 millibars (mbar) to about 300 mbar, and preferably about 50 mbar to about 150 mbar.

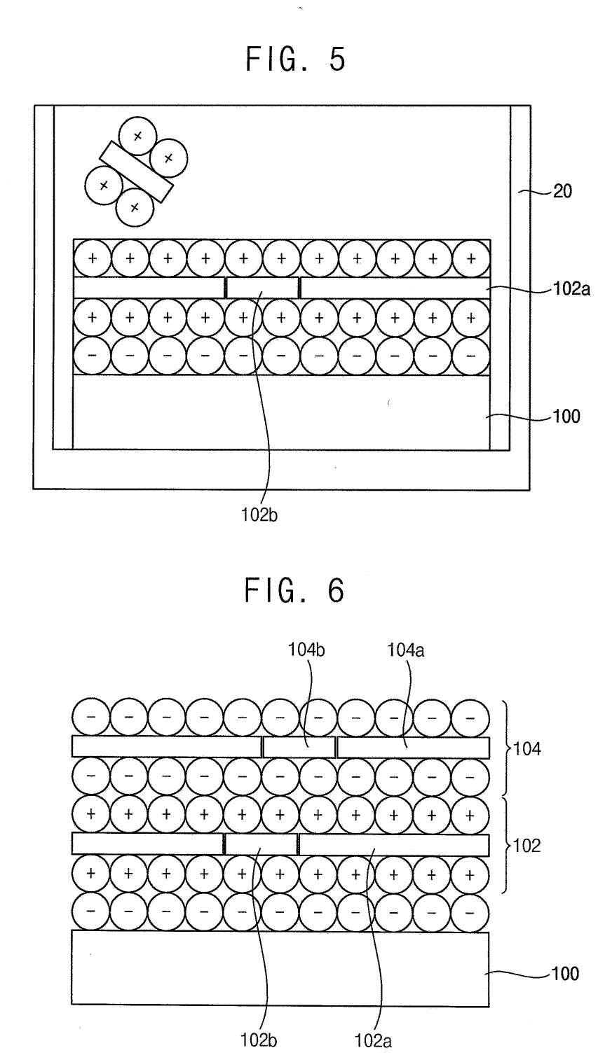

Gas in the gap GA of the graphene-oxide layer may be removed through the heating and pressure-reducing process so that the solution including the second graphene-oxide flake 102b may be easily entered into the gap GA. Thus, the second graphene-oxide flake 102b may be adhered to the surface of the substrate 100, as illustrated in FIG. 5. In this exemplary embodiment show in FIG. 5, since the surface of the substrate 100 is negatively electric-charged, the second graphene-oxide flake 102b may be combined with the surface of the substrate 100, which is negatively electric-charged, by electrostatic force.

Thereafter, drying and rinsing may be performed to the substrate 100.

Accordingly, a first graphene-oxide layer 102 having uniformity improved by combination of the first graphene-oxide flake 102a and the second graphene-oxide flake 102b is formed.

Referring to FIG. 6, a second graphene-oxide layer 104 is formed on the first graphene-oxide layer 102. The second graphene-oxide layer 104 may include graphene-oxide flakes which are charged with an polarity opposite to the first graphene-oxide layer 102 (e.g., negatively electric-charged), and may be formed by a substantially same method as the first graphene-oxide layer 102. Thus, the second graphene-oxide layer 104 may include a first graphene-oxide flake 104a and a second graphene-oxide flake 104b smaller than the first graphene-oxide flake 104a.

The above processes may be repeated to form a stacked structure of graphene oxide layers bonded between the layers by electrostatic force. In an exemplary embodiment, for example, the stacked structure of the graphene-oxide layers may have a thickness of about 2 nanometers (nm) to about 20 nm, and may be formed by repeatedly forming the combination of the positively electric-charged graphene oxide layer and the negatively electric-charged graphene oxide layer by 1 to 10 times. In other words, the stacked structure of the graphene-oxide layers may be formed by alternatively stacking the positively electric-charged graphene oxide layer and the negatively electric-charged graphene oxide layer.

The stacked structure may be used as a barrier adhesion layer for separating a carrier substrate and a flexible substrate from each other in a method for manufacturing a display device. Hereinafter, the method using the stacked structure will be described in detail.

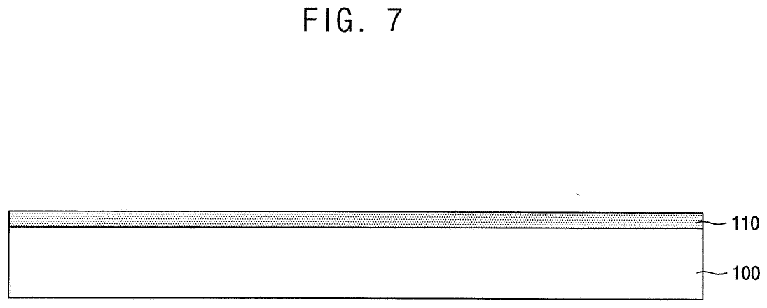

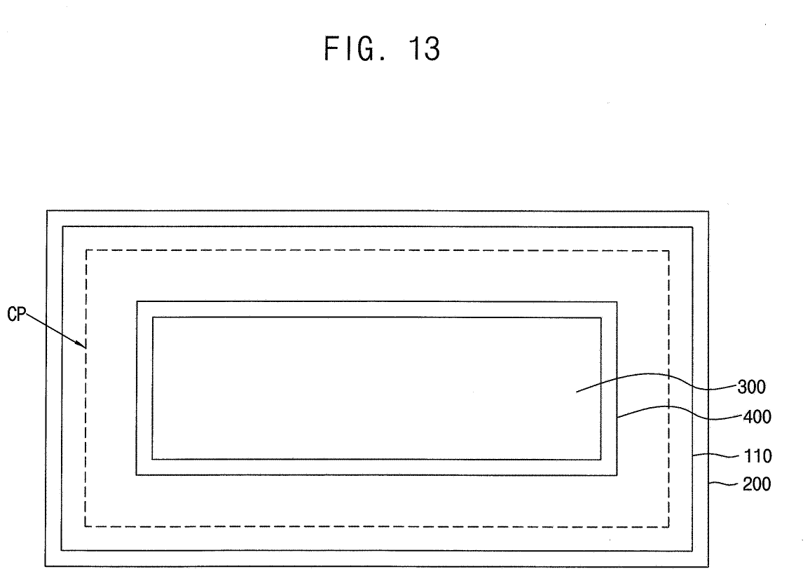

FIGS. 7 to 12 and 14 to 17 are cross-sectional views illustrating exemplary embodiments of a method for manufacturing a display device according to the invention. FIG. 13 is a plan view illustrating an exemplary embodiment of a cutting process in a method for manufacturing a display device according to the invention.

Referring to FIG. 7, a barrier adhesion layer 110 is formed on a carrier substrate 100.

The carrier substrate 100 supports a flexible substrate 200 in the process of manufacturing a flexible display device. In an exemplary embodiment, for example, the carrier substrate 100 may include glass, quartz, silicon, polymers or the like.

The barrier adhesion layer 110 may include barrier flakes. For example, the barrier flake may include graphene, graphene oxide, hexagonal boron nitride or the like. In an exemplary embodiment, the barrier flake may include graphene oxide.

Graphene oxide has physical characteristics similar to graphene and has superior dispersion ability. Thus, aqueous solution process may be used for forming a thin layer by using the graphene oxide.

In an exemplary embodiment, the barrier adhesion layer 110 may be formed through a layer-by-layer method. For example, the barrier adhesion layer 110 may be formed by alternately depositing a first barrier layer which is charged with a first electric charge, and a second barrier layer which is charged with a second electric charge having an opposite polarity to the first electric charge. The first electric charge is one of a negative electric charge and a positive electric charge, and the second electric charge is the other. The barrier layers electric-charged with opposite polarities may be alternatively combined with each other by electrostatic force. The method for forming the barrier adhesion layer 110 may be substantially the same as the method previously explained with reference to FIGS. 1 to 6. Thus, any duplicated explanation may be omitted.

The barrier adhesion layer 110 has superior barrier ability, thereby preventing a strong chemical bond from being formed between the flexible substrate 200 and the carrier substrate 100 due to inflow of a deposition source such as silane in the process of forming the display element part. Furthermore, the barrier adhesion layer 110 has a relatively low adhesion force with compared to other adhesives. Thus, after the display element part is formed, the carrier substrate 100 may be easily separated from the flexible substrate 200.

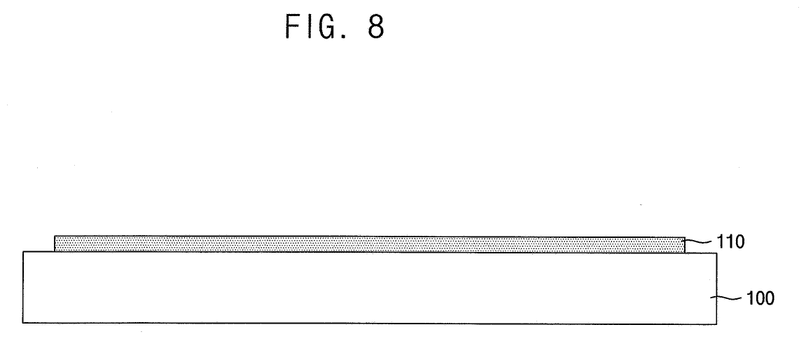

Referring to FIG. 8, an edge of the barrier adhesion layer 110 is removed to partially expose an upper surface of the carrier substrate 100.

For example, a plasma torch may be used, or an alkali material such as tetramethylammonium hydroxide (“TMAH”) may be applied, in order to pattern the barrier adhesion layer 110.

The edge of the barrier adhesion layer 110 is removed to partially expose an upper surface of the carrier substrate 100 so that an edge of the flexible substrate 200, which will be formed on the barrier adhesion layer 110, may contact the exposed upper surface of the carrier substrate 100. Thus, if the barrier adhesion layer 110 has a shape already partially exposing the upper surface of the carrier substrate 100, the step of removing the edge of the barrier adhesion layer 110 may be omitted.

Thereafter, the barrier adhesion layer 110 may be baked. Through baking, a solvent remaining in the barrier adhesion layer 110 may be removed, and a density of the barrier adhesion layer 110 may increase. In an exemplary embodiment, for example, a temperature for the baking process may be about 300° C. to about 500° C.

In an exemplary embodiment, for example, an adhesion force of the barrier adhesion layer 110 may be about 1 Gram-force/inch (gf/in) to about 5 gf/in.

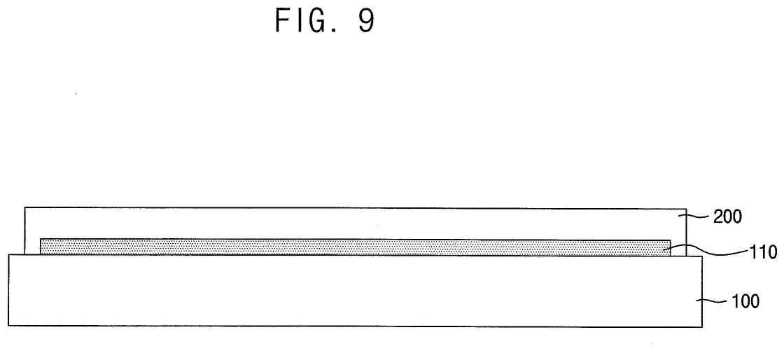

Referring to FIG. 9, the flexible substrate 200 is formed on the barrier adhesion layer 110. For example, a composition including a polymer or a monomer capable of forming a polymer may be coated on the barrier adhesion layer 110, and then dried or cured to form the flexible substrate 200.

In an exemplary embodiment, for example, the flexible substrate 200 may include polyester, polyvinyl, polycarbonate, polyethylene, polypropylene, polyacetate, polyimide, polyethersulphone (“PES”), polyacrylate (“PAR”), polyethylenenaphthelate (“PEN”), polyethyleneterephehalate (“PET”), or a combination thereof.

In an exemplary embodiment, the flexible substrate 200 may include polyimide which has superior mechanical characteristics and heat resistance.

In an exemplary embodiment, an edge of the flexible substrate 200 contacts the carrier substrate 100. Thus, a side surface of the barrier adhesion layer 110 may be covered by the flexible substrate 200. If the flexible substrate 200 is entirely spaced apart from the carrier substrate 100 by the barrier adhesion layer 110 without contacting between edges of the carrier substrate 100 and flexible substrate 200 in the process of forming the display element part, the flexible substrate 200 may be separated from the carrier substrate 100, or dislocation between the flexible substrate 200 and the carrier substrate 100 may be caused, due to the low adhesive force of the barrier adhesion layer 110 before a cutting process which will be explained later.

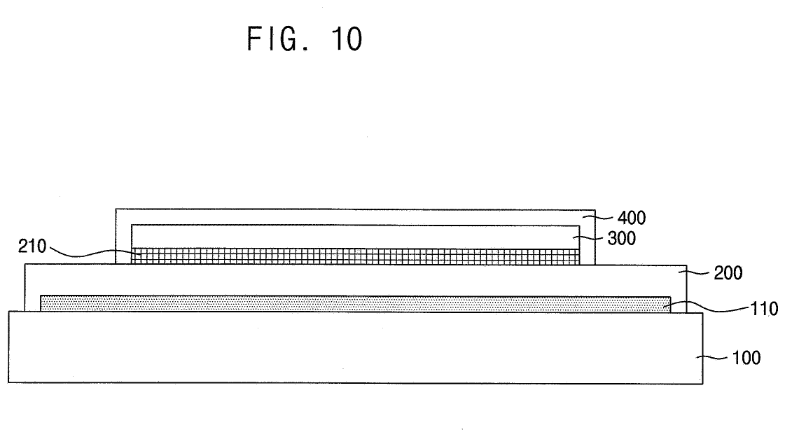

Referring to FIG. 10, a first inorganic barrier layer 210 is formed on the flexible substrate 200. A display element part 300 and a protective film 400 covering the display element part 300 are formed on the first inorganic barrier layer 210.

The first inorganic barrier layer 210 may prevent external impurities from penetrating into the display element part 300.

For example, the first inorganic barrier layer 210 may include an inorganic material. In an exemplary embodiment, for example, the inorganic material may include silicon oxide, silicon nitride, silicon oxynitride, silicon carbide, silicon oxycarbide or a combination thereof. The first inorganic barrier layer 210 may have a single-layer structure or a multi-layer structure including a plurality of layers including different materials.

In an exemplary embodiment, the first inorganic barrier layer 210 may include a multi-layer structure of a silicon oxide (SiO₂) layer, a silicon nitride (SiN) layer, and a silicon oxynitride (SiON) layer. In an exemplary embodiment, for example, a thickness of the silicon oxide layer may be about 2,000 angstroms (Å) to about 10,000 Å, the thickness of a silicon nitride layer may be about 100 Å to about 1,000 Å, and the thickness of a silicon oxynitride layer may be bout 2,000 Å to about 10,000 Å. The multi-layer structure may effectively prevent or inhibit penetration of humidity or particles.

For example, the first inorganic barrier layer 210 may be formed through chemical vaporization deposition (“CVD”), plasma-enhanced chemical vaporization deposition (“PECVD”), physical deposition, atomic layer deposition (“ALD”) or the like.

The first inorganic barrier layer 210 is shown to partially cover a surface of the flexible substrate 200 in FIG. 10, however, the invention is not limited thereto. In another exemplary embodiment, for example, the first inorganic barrier layer 210 may be formed entirely on the upper surface of the flexible substrate 200.

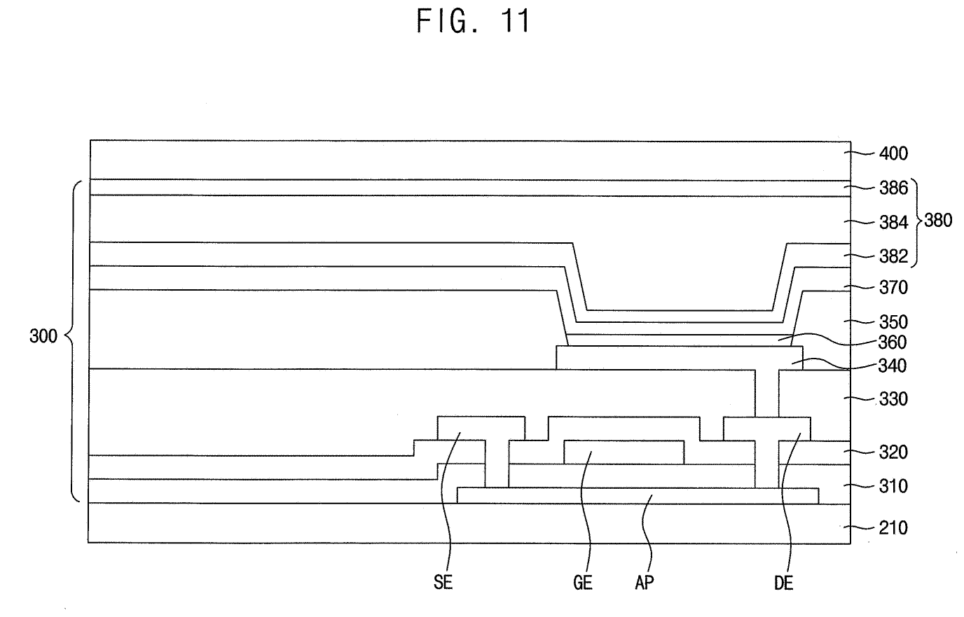

FIG. 11 is an enlarged cross-sectional view illustrating an exemplary embodiment of a display element part of a flexible display device according to the invention.

Referring to FIG. 11, the display element part 300 may include a pixel circuit, an organic light-emitting diode electrically connected to the pixel circuit, and a thin film encapsulation layer covering the organic light-emitting diode.

The pixel circuit may include an active pattern AP, a gate electrode GE overlapping the active pattern AP in a plan view, a source electrode SE electrically connected to the active pattern AP, and a drain electrode DE spaced apart from the source electrode SE and electrically connected to the active pattern AP.

The active pattern AP may be disposed on the first inorganic barrier layer 210. The active pattern AP may overlap the gate electrode GE.

In an exemplary embodiment, for example, the active pattern AP may include a semiconductor material such as amorphous silicon, polycrystalline silicon (polysilicon), oxide semiconductor or the like. For example, in the case that the active pattern AP includes polysilicon, at least a portion of the active pattern AP may be doped with impurities such as n-type impurities or p-type impurities.

A first insulation layer 310 may be disposed on the active pattern AP. In an exemplary embodiment, for example, the first insulation layer 310 may include silicon oxide, silicon nitride, silicon oxynitride, silicon carbide, silicon oxycarbide or a combination thereof. Furthermore, the first insulation layer 310 may include an insulating metal oxide such as aluminum oxide, tantalum oxide, hafnium oxide, zirconium oxide, titanium oxide or the like. For example, the first insulation layer 310 may have a single-layer structure or a multiple-layer structure including silicon nitride and/or silicon oxide.

The gate electrode GE may be disposed on the first insulation layer 310. In an exemplary embodiment, for example, the gate electrode GE may include gold (Au), silver (Ag), aluminum (Al), copper (Cu), nickel (Ni), platinum (Pt), magnesium (Mg), chromium (Cr), tungsten (W), molybdenum (Mo), titanium (Ti), tantalum (Ta) or an alloy thereof, and may have a single-layer structure or a multiple-layer structure including different metal layers.

A second insulation layer 320 may be disposed on the gate electrode GE and the first insulation layer 310. In an exemplary embodiment, for example, the second insulation layer 320 may include silicon oxide, silicon nitride, silicon oxynitride, silicon carbide, silicon oxycarbide or a combination thereof. Furthermore, the second insulation layer 320 may include an insulating metal oxide such as aluminum oxide, tantalum oxide, hafnium oxide, zirconium oxide, titanium oxide or the like.

A data metal pattern including the source electrode SE and the drain electrode DE may be disposed on the second insulation layer 320. The source electrode SE and the drain electrode DE may pass through the first insulation layer 310 and the second insulation layer 320 to contact the active pattern AP, respectively. In an exemplary embodiment, for example, the source electrode SE and the drain electrode DE may include gold (Au), silver (Ag), aluminum (Al), copper (Cu), nickel (Ni), platinum (Pt), magnesium (Mg), chromium (Cr), tungsten (W), molybdenum (Mo), titanium (Ti), tantalum (Ta) or an alloy thereof, and may have a single-layer structure or a multiple-layer structure including different metal layers.

A third insulation layer 330 may be disposed on the data metal pattern and the second insulation layer 320. For example, the third insulation layer 330 may include an inorganic insulation material, an organic insulation material or a combination thereof. In an exemplary embodiment, for example, the organic insulation material may include polyimide, polyamide, acrylic resin, phenol resin, benzocyclobutene (“BCB”) or the like.

A first electrode 340 of the organic light-emitting diode may be disposed on the third insulation layer 330. In an exemplary embodiment, the first electrode 340 may function as an anode. For example, the first electrode 340 may be formed as a transmitting electrode or a reflecting electrode according to an emission type of the display device. In the case that the first electrode 340 is a transmitting electrode, the first electrode 340 may include indium tin oxide, indium zinc oxide, zinc tin oxide, indium oxide, zinc oxide, tin oxide or the like, for example. In the case that the first electrode 340 is a reflecting electrode, the first electrode 340 may include, for example, gold (Au), silver (Ag), aluminum (Al), copper (Cu), nickel (Ni), platinum (Pt), magnesium (Mg), chromium (Cr), tungsten (W), molybdenum (Mo), titanium (Ti) or a combination thereof, and may have a stacked structure further including the material that may be used for the transmitting electrode.

A pixel-defining layer 350 may be disposed on the third insulation layer 330. The pixel-defining layer 350 may define an opening that exposes at least a portion of the first electrode 340. For example, the pixel-defining layer 350 may include an organic insulation material. For example, the pixel-defining layer 350 and the third insulation layer 330 may be formed by coating a photoresist composition including an organic insulation material and patterning a coating layer using exposure-development processes.

An organic light-emitting layer 360 may be disposed on the first electrode 340. A common layer 370 may be disposed on the organic light-emitting layer 360. The common layer 370 may include at least one layer extending continuously across a plurality of pixels in a display area.

In an exemplary embodiment, the organic light-emitting layer 360 may have a patterned shape disposed in an opening defined by the pixel-defining layer 350. However, the invention is not limited thereto, and the organic light-emitting layer 360 may continuously extend across a plurality of pixels in a display area, like the common layer 370.

In an exemplary embodiment, for example, the organic light-emitting layer 360 may include at least one of a hole injection layer (“HIL”), a hole transporting layer (“HTL”), a light-emitting layer, an electron transporting layer (“ETL”) and an electron injection layer (“EIL”). For example, the organic light-emitting layer 360 may include a low molecular weight organic compound or a high molecular weight organic compound.

In an exemplary embodiment, the organic light-emitting layer 360 may emit a red light, a green light or a blue light. In another exemplary embodiment, the organic light-emitting layer 360 may emit a white light. The organic light-emitting layer 360 emitting a white light may have a multiple-layer structure including a red-emitting layer, a green-emitting layer and a blue-emitting layer, or a single-layer structure including a mixture of a red-emitting material, a green-emitting material and a blue-emitting material.

For example, the common layer 370 may include at least a second electrode of the organic light-emitting diode, and may further include a capping layer and/or a blocking layer on the second electrode.

In an exemplary embodiment, the second electrode may function as a cathode. For example, the second electrode may be formed as a transmitting electrode or a reflecting electrode according to an emission type of the display device. For example, in the case that the second electrode is a transmitting electrode, the second electrode may include lithium (Li), calcium (Ca), lithium fluoride (LiF), aluminum (Al), magnesium (Mg), or a combination thereof, and the display device may further include a sub electrode or a bus electrode line which includes indium tin oxide, indium zinc oxide, zinc tin oxide, indium oxide, zinc oxide, tin oxide, or the like.

The capping layer may be disposed on the second electrode. The capping layer may protect the organic light-emitting diode and may promote the light generated by the organic light-emitting diode to exit outwardly. For example, the capping layer may include an inorganic material or an organic material.

The blocking layer may be disposed on the capping layer. The blocking layer may prevent damage to the organic light-emitting diode by plasma or the like from later processes. For example, the blocking layer may include lithium fluoride, magnesium fluoride, calcium fluoride or the like.

The thin film encapsulation layer 380 may be disposed on the common layer 370. The thin film encapsulation layer 380 may have a stacked structure of an inorganic layer and an organic layer. For example, the thin film encapsulation layer 380 may include a first inorganic layer 382, a second inorganic layer 386 and an organic layer 384 disposed between the first and second inorganic layers 382 and 386.

For example, the organic layer 384 may include a cured resin such as polyacrylate or the like. For example, the cured resin may be formed from cross-linking reaction of monomers.

In an exemplary embodiment, for example, the first and second inorganic layers 382 and 386 may include an inorganic material such as silicon oxide, silicon nitride, silicon carbide, aluminum oxide, tantalum oxide, hafnium oxide, zirconium oxide, titanium oxide or the like, and may be formed by chemical vaporization deposition (CVD).

The organic layer 384 may be formed on the first inorganic layer 382. For example, a monomer composition may be provided on an upper surface of the first inorganic layer 382 to form the organic layer 384.

The monomer composition may include a curable monomer. For example, the curable monomer may contain at least one curable functional group. In an exemplary embodiment, for example, the curable functional group may include a vinyl group, a (meth)acrylate group, an epoxy group or the like.

In an exemplary embodiment, for example, the curable monomer may include ethyleneglycol di(meth)acrylate, hexanediol di(meth)acrylate, heptanediol di(meth)acrylate, octanediol di(meth)acrylate, nonanediol di(meth)acrylate, decanediol di(meth)acrylate, triethylpropane tri(meth)acrylate, pentaerythritol tri(meth)acrylate, pentaerythritol tetra(meth)acrylate, dipentaerythritol tri(meth)acrylate, dipentaerythritol tetra(meth)acrylate, dipentaerythritol penta(meth)acrylate, dipentaerythritol hexa(meth)acrylate or the like.

The monomer composition may further include an initiator such as a photo initiator or the like.

The monomer composition may be provided on the first inorganic layer 382 through ink-jet printing, screen printing or the like, and may be cured to form the cured resin.

The invention is not limited to the above-explained configuration of the thin film encapsulation layer 380. In another exemplary embodiment, for example, the thin film encapsulation layer 380 may include at least two organic layers or at least three inorganic layers.

The protective film 400 may cover an upper surface of the thin film encapsulation layer 380. For example, the protective film 400 may include a polymer film or the like.

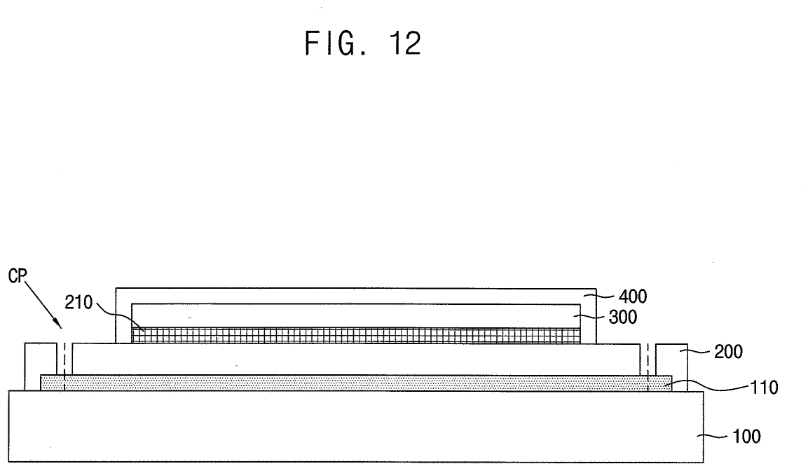

Hereinafter, a process of separating the flexible substrate 200 from the carrier substrate 100 will be explained with reference to FIGS. 12 to 17.

Referring to FIGS. 12 and 13, a cutting portion CP is defined at an edge of the flexible substrate 200. For example, the cutting portion CP may be defined in an area where the flexible substrate 200 and the barrier adhesion layer 110 overlap each other in the plan view. In an exemplary embodiment, a cutting line of the cutting portion CP may be disposed between an outer boundary of the barrier adhesion layer 110 and an outer boundary of the display element part 300, in the plan view. For example, the flexible substrate 200 may be cut along the cutting line surrounding the display element part 300 with a laser, a knife or the like.

In an exemplary embodiment, an area where the carrier substrate 100 directly contacts the flexible substrate 200 and an area where the carrier substrate 100 overlaps the display element part 300 in the plan view may be preferably separated from each other by the cutting portion CP. In the case that the area where the carrier substrate 100 directly contacts the flexible substrate 200 and the area where the carrier substrate 100 overlaps the display element part 300 are separated from each other, the process of separating the carrier substrate 100 from flexible substrate 200 may be easily performed without interference by the strong bond between the carrier substrate 100 and flexible substrate 200.

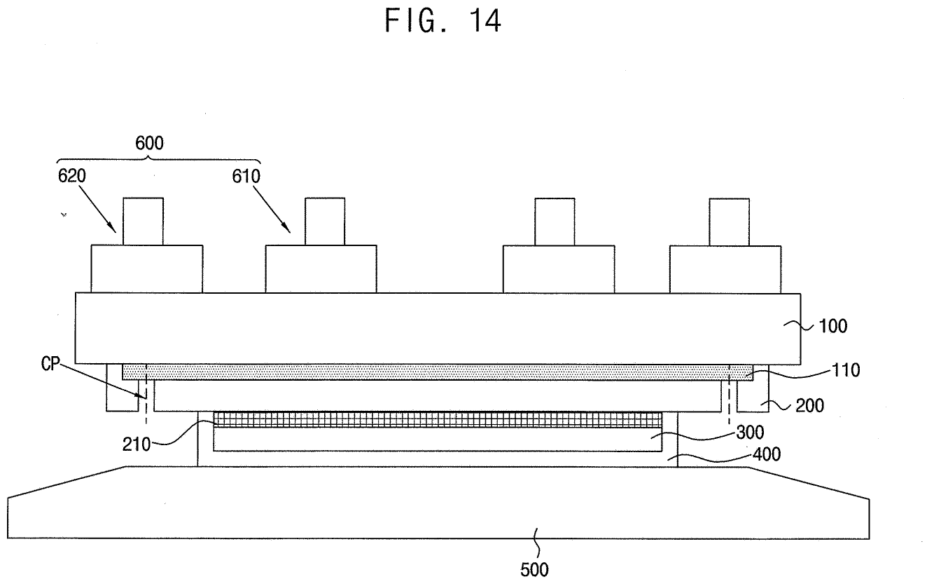

Referring to FIG. 14, the protective film 400 is combined with a fixing stage 500, and the carrier substrate 100 is combined with a fixing member 600.

For example, vacuum or negative pressure may be provided to the fixing stage 500 and the fixing member 600 so that the fixing stage 500 and the fixing member 600 may be combined with the protective film 400 and the carrier substrate 100, respectively.

The fixing member 600 may include a plurality of fixing pads. For example, the fixing member 600 may include a first fixing member 610 combined with an area overlapping the display element part 300, and a second fixing member 620 combined with an area overlapping the cutting portion CP in the plan view.

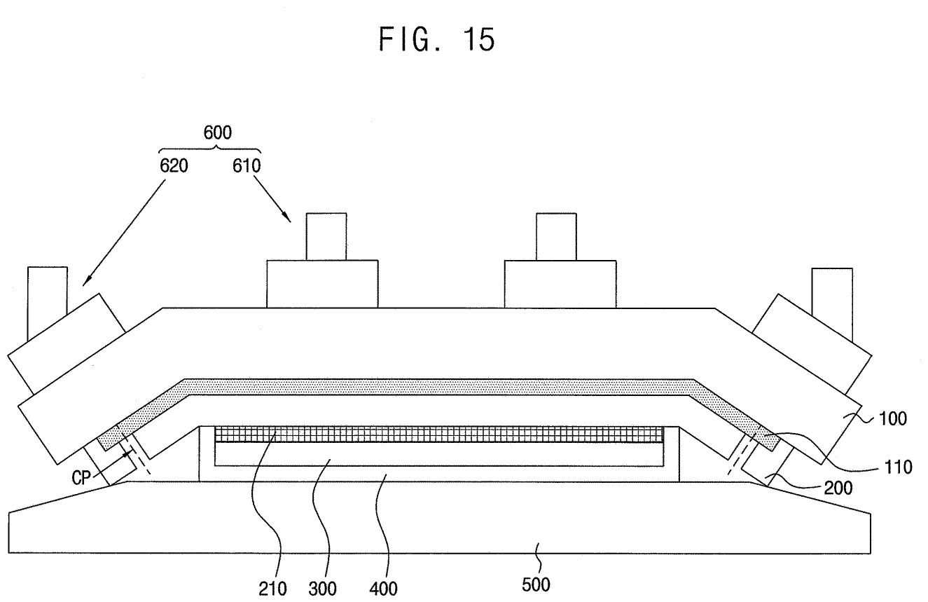

Referring to FIG. 15, the second fixing member 620 combined with the area overlapping the cutting portion CP may move downwardly and toward the fixing stage 500. Thus, a region near an edge of the flexible substrate 200 may bend so that the edge of the flexible substrate 200 may contact the fixing stage 500. Since the fixing stage 500 provides vacuum or negative pressure, the edge of the flexible substrate 200 may be adsorbed onto and combined with the fixing stage 500.

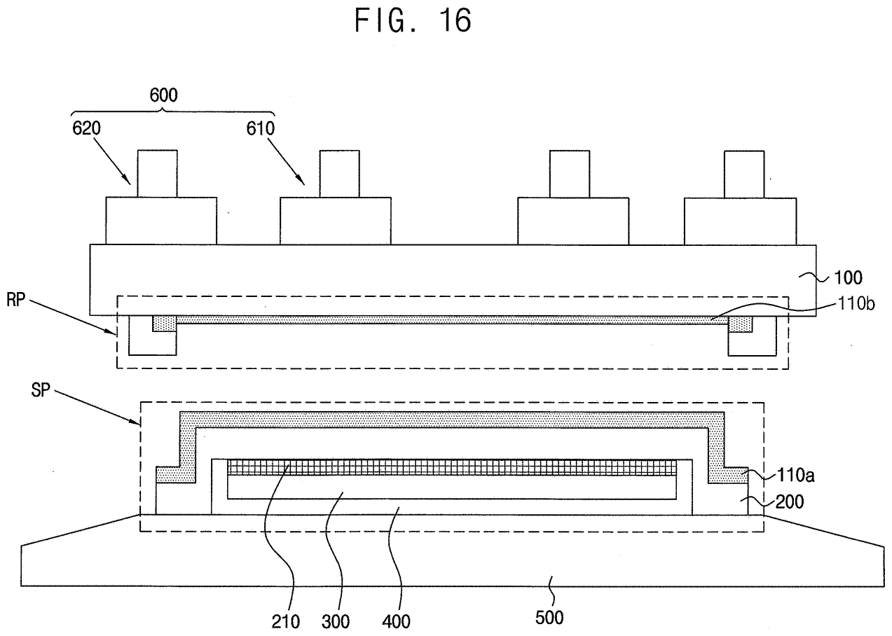

Referring to FIG. 16, the fixing member 600 combined with the carrier substrate 100 may move upwardly to separate the flexible substrate 200 from the carrier substrate 100.

As explained in the above, the barrier adhesion layer 110 has a relatively low adhesion force. Thus, if external forces are applied to the flexible substrate 200 and the carrier substrate 100 in opposite, outward directions, respectively, the flexible substrate 200 and the carrier substrate 100 may be easily separated from each other without an additional process such as radiating a laser.

The portion of the flexible substrate 200 where the carrier substrate 100 directly contacts may be separated from a separated portion SP combined with the fixing stage 500 when the external forces are applied. A strong bond is formed at an interface between the carrier substrate 100 and the portion of the flexible substrate 200. Thus, the flexible substrate 200 may be divided into the separated portion SP and a remaining portion RP (i.e., the portion of the flexible substrate 200 where the carrier substrate 100 directly contacts). The remaining portion RP may be combined with the carrier substrate 100.

The barrier adhesion layer 110 includes a plurality of the graphene oxide layers electric-charged and alternately deposited. Thus, when a physical external force is applied to the barrier adhesion layer 110, an interlayer combination by electrostatic force is broken thereby causing the separation between layers. Thus, a first portion 110a of the barrier adhesion layer 110 may adhere to the flexible substrate 200, and a second portion 110b of the barrier adhesion layer 110 may adhere to the carrier substrate 100 after the flexible substrate 200 is separated from the carrier substrate 100.

In an exemplary embodiment, before the flexible substrate 200 is separated from the carrier substrate 100 by the external forces applied thereto in opposite, outward directions, the carrier substrate 100 and the flexible substrate 200 are bended so that the flexible substrate 200 may contact the fixing stage 500 directly as shown in FIGS. 15 and 16. Thus, the flexible substrate 200 may be adsorbed onto and combined with the fixing stage 500, and the external force may be directly applied to the flexible substrate 200.

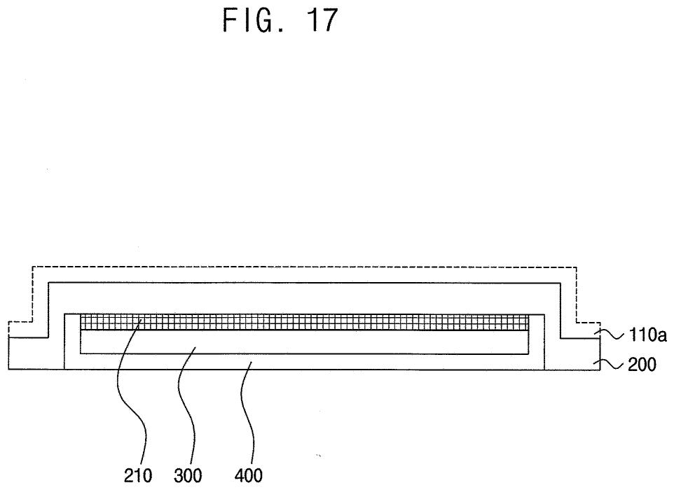

Referring to FIG. 17, the portion 110a of the barrier adhesion layer 110 remaining on the flexible substrate 200 is removed.

For example, the remaining portion 110a of the barrier adhesion layer 110 may be removed by a wet method using TMAH or a dry method using plasma or the like.

As desired, an additional barrier layer may be formed on the surface of the flexible substrate 200 from which the remaining portion 110a of the barrier adhesion layer 110 is removed after the removal.

According to exemplary embodiments, a barrier adhesion layer is disposed between a carrier substrate and a flexible substrate. Thus, a chemical bond between the carrier substrate and the flexible substrate may be prevented, and the carrier substrate may be mechanically separated from the flexible substrate without a laser-radiation process or the like.

Furthermore, when a single layer of the barrier adhesion layer is formed, after a first barrier flake is provided to form a preliminary layer, a second barrier flake smaller than the first barrier flake is provided to fill a gap where the first barrier flake is not attached. Thus, defects of the barrier adhesion layer may be reduced, thereby increasing uniformity of the barrier adhesion layer. Thus, reliability of a flexible substrate formed on the barrier adhesion layer may be improved, and separation of the flexible substrate and the carrier substrate may be easily performed.

Furthermore, since the first barrier flake and the second barrier flake are provided through combination of dipping and spraying, a manufacturing time may be reduced, and defects due to spraying may be prevented or reduced.

Exemplary embodiments may be used for forming various stacked structures bonded between inner layers by electrostatic force. For example, exemplary embodiments may be applied to fabrication of a flexible display device for a computer, a notebook computer, a tablet computer, a smart phone, a mobile phone, a navigator, a PDA, an audio player, an automobile, a home appliance, a wearable device or the like.

The foregoing is illustrative of exemplary embodiments and is not to be construed as limiting thereof. Although exemplary embodiments have been described, those skilled in the art will readily appreciate that many modifications are possible in the exemplary embodiments without materially departing from the novel teachings and aspects of the invention. Accordingly, all such modifications are intended to be included within the scope of the invention. Therefore, it is to be understood that the foregoing is illustrative of various exemplary embodiments and is not to be construed as limited to the specific exemplary embodiments disclosed, and that modifications to the disclosed exemplary embodiments, as well as other exemplary embodiments, are intended to be included within the scope of the invention, as set forth in the following claims and equivalents thereof.

What is claimed is:

1. A method of forming a stacked structure, the method comprising:
adhering a first barrier flake charged with a first electric charge to a surface of a substrate, the first barrier flake being provided in plural;
providing a second barrier flake in a gap between adjacent first barrier flakes to form a first barrier layer charged with the first electric charge, the second barrier flake having a size smaller than a size of the first barrier flake; and
forming a second barrier layer on the first barrier layer, wherein the second barrier layer is charged with a second electric charge having a polarity opposite to the first electric charge to be combined with the first barrier layer by an electro-static force.

2. The method of claim 1, wherein the first and second barrier flakes include at least one of graphene, graphene oxide or hexagonal boron nitride.

3. The method of claim 1, further comprising charging the surface of the substrate with the second electric charge before adhering the first barrier flake to the surface of the substrate.

4. The method of claim 1, wherein providing the second barrier flake comprises dipping the substrate combined with the first barrier flakes in a solution including the second barrier flake.

5. The method of claim 4, wherein providing the second barrier flake further comprises performing a heating and pressure-reducing process to remove gas in the gap between the adjacent first barrier flakes with the substrate dipped in the solution.

6. The method of claim 5, wherein the heating and pressure-reducing process is performed at about 40 degrees Celsius (° C.) to about 80 degrees Celsius (° C.) and at about 50 millibars (mbar) to about 300 millibars (mbar).

7. The method of claim 1, wherein the first barrier flake has a size equal to or more than about 10 micrometers (μm) and equal to or less than about 50 micrometers (μm).

8. The method of claim 7, wherein the second graphene oxide flake has a size equal to or more than about 1 micrometer (μm) and less than about 10 micrometers (μm).

9. The method of claim 1, wherein a thickness of the stacked structure is about 2 nanometers (nm) to about 20 nanometers (nm).

10. A method for manufacturing a display device, the method comprising:
adhering a first barrier flake charged with a first electric charge to a surface of a carrier substrate, the first barrier flake being provided in plural;
providing a second barrier flake in a gap between adjacent first barrier flakes to form a first barrier layer charged with the first electric charge, the second barrier flake having a size smaller than a size of the first barrier flake;
forming a second barrier layer charged on the first barrier layer, wherein the second barrier layer is charged with a second electric charge having a polarity opposite to the first electric charge to be combined with the first barrier layer by an electro-static force;
forming a flexible substrate on a barrier adhesion layer including the first barrier layer and the second barrier layer;
forming a display element part on the flexible substrate;
forming a protective film on the display element part; and
separating the flexible substrate from the carrier substrate.

11. The method of claim 10, wherein the flexible substrate includes at least one of polyester, polyvinyl, polycarbonate, polyethylene, polypropylene, polyacetate, polyimide, polyethersulphone (PES), polyacrylate (PAR), polyethylenenaphthelate (PEN) or polyethyleneterephehalate (PET).

12. The method of claim 10, wherein the first and second barrier flakes include at least one of graphene, graphene oxide or hexagonal boron nitride.

13. The method of claim 10, further comprising:
charging the surface of the carrier substrate with the second electric charge before adhering the first barrier flake to the surface of the carrier substrate.

14. The method of claim 10, wherein providing the second barrier flake comprises dipping the carrier substrate combined with the first barrier flakes in a solution including the second barrier flake.

15. The method of claim 14, wherein providing the second barrier flake further comprises performing a heating and pressure-reducing process to remove gas in the gap between the adjacent first barrier flakes with the carrier substrate dipped in the solution.

16. The method of claim 15, wherein the heating and pressure-reducing process is performed at about 40 degrees Celsius (° C.) to about 80 degrees Celsius (° C.) and at about 50 millibars (mbar) to about 300 millibars (mbar).

17. The method of claim 14, wherein the first barrier flakes are provided as a solution on the carrier substrate by spraying, wherein a concentration of the second barrier flake in the solution including the second barrier flake is greater than a concentration of the first barrier flakes in the solution including the first barrier flakes.

18. The method of claim 10, wherein the first barrier flake has a size equal to or more than about 10 micrometers (μm) and equal to or less than about 50 micrometers (μm).

19. The method of claim 18, wherein the second graphene oxide flake has a size equal to or more than about 1 micrometers (μm) and less than about 10 micrometers (μm).

20. The method of claim 10, wherein a thickness of the stacked structure is about 2 nanometers (nm) to about 20 nanometers (nm).
